(19) United States
(12) Patent Application Publication
(10) Pub. No.: US 2026/0280406 A1
(43) Pub. Date: Sep. 17, 2026

(54) UPPER ARM DRIVE CIRCUIT AND POWER CONVERSION DEVICE

(71) Applicant: Minebea Power Semiconductor Device Inc., Ibaraki (JP)

(72) Inventors: Satoshi IESAKA, Hitachi-shi (JP); Kenji SAKURAI, Hitachi-shi (JP); Yoshiro MATSUMOTO, Hitachi-shi (JP)

(21) Appl. No.: 19/471,437

(22) PCT Filed: Feb. 1, 2024
(86) PCT No.: PCT/JP2024/003264

§ 371 Date: Oct. 1, 2025

(30) Foreign Application Priority Data
Apr. 27, 2023 (JP) 2023-073391

(51) Int. Cl. H02M 1/00; H02M 1/088; H02M 3/158

(52) U.S. Cl. CPC H02M 1/0051; H02M 1/088; H02M 3/158

(57) ABSTRACT

An upper arm drive circuit includes a first switching element connected between a gate electrode of an upper arm switching element and a main electrode on a reference potential side of an upper arm switching element. A second switching element having a drain electrode is connected to the gate electrode of the upper arm switching element. First and second diodes are arranged between the drain electrode and the gate electrode of the upper arm switching element, the first and second diodes being arranged in series with cathodes on a side of the second switching element and anodes on a side of the upper arm switching element. A withstand voltage of the second diode is lower than that of the first diode. A recovery current of the second diode is lower than that of the first diode. A withstand voltage of the first diode ranges from 60 to 100 V.

### TECHNICAL FIELD

The present invention relates to an upper arm drive circuit and a power conversion device.

BACKGROUND ART

For example, PTL 1 discloses a technique related to an upper arm drive circuit of a power conversion device.

FIG. 1 and paragraph 0024 of PTL 1 describe that “when the upper arm QT1 is turned off, the switching element S2 is turned on, and the charge retained in the input capacitance of QT1 is reversely biased and extracted. However, since the extraction current 12 has an element that increases power consumption similarly to a level shift circuit, pulse driving may be employed in order to lower power consumption. In this case, since QT1 becomes completely indefinite after the pulse driving, means of another circuit to hold off is required. This function is performed by turning on the N-channel switching element M1”.

### CITATION LIST

### Patent Literature

PTL 1: JP 11-313488 A

### SUMMARY OF INVENTION

### Technical Problem

However, PTL 1 assumes an ideal case, and actually, there is a problem that after the gate charge of the upper arm QT1 is extracted using the switching element S2 and the switching element M1 when the upper arm QT1 is turned off, the output becomes a negative voltage due to the reflux of the reflux diode DB1 of the lower arm QB1, and the current may flow back from the switching element S2.

As a method for solving this problem, it is conceivable to provide a diode for preventing backflow of current in front of the switching element S2.

FIG. 4 is a circuit diagram of an upper arm drive circuit and a power conversion device of a comparative example.

In FIG. 4, an upper arm switching element Q1, a first switching element SW1, and a second switching element SW2 correspond to the upper arm QT1, the switching element M1, and the switching element S2 of PTL 1, respectively. A first diode D1 for preventing backflow of current is provided between the second switching element SW2 and a gate electrode of the upper arm switching element Q1.

FIG. 5 is a waveform chart for explaining an ideal operation of the comparative example. FIG. 6 is a waveform chart for explaining an actual operation of the comparative example. In FIGS. 5 and 6, the vertical axis represents an output terminal voltage VOUT which is a voltage from an output terminal OUT, a voltage VD1 of the first diode (the withstand voltage direction is assumed to be positive), an upper arm OFF current IOFF, and the horizontal axis represents time t.

As illustrated in FIG. 5, when a drive signal applied to the gate electrode of the upper arm switching element Q1 changes from an on (ON) signal to an off (OFF) signal at time t1, the first switching element SW1 and the second switching element SW2 are turned on, so that the gate charge of the upper arm switching element Q1 is extracted. Accordingly, from the time t1 to time t2, a forward voltage is applied to the first diode D1 and flows in the forward direction, and the upper arm OFF current IOFF flows.

After delay time T1 from the time t1, a freewheeling current IDQ2 flows through a lower arm freewheeling diode DQ2 reversely connected to the lower arm switching element Q2, and at the time t2, a forward voltage VF of the lower arm freewheeling diode is generated in the output terminal voltage VOUT.

At this time, the first diode D1 is reversely biased by the forward voltage VF of the lower arm freewheeling diode, the upper arm OFF current IOFF does not flow, and ideally, the backflow of the current is prevented by the first diode D1.

However, in practice, as illustrated in FIG. 6, there is a problem that recovery of the first diode D1 occurs, and a recovery current IR of the first diode D1 flows in the reverse direction in a recovery period T2 between the time t2 and time t3, and malfunction of the circuit such as turning on of the upper arm switching element Q1 occurs.

Since there is a trade-off that the withstand voltage of the diode decreases in order to reduce the recovery, the first diode D1 needs to have a withstand voltage higher than the forward voltage VF of the lower arm freewheeling diode. Therefore, it is difficult to reduce the recovery current IR.

An object of the present invention is to provide an upper arm drive circuit and a power conversion device that are capable of suppressing malfunction of an upper arm switching element when a freewheeling current flows through a lower arm.

### Solution to Problem

In order to solve the above problem, provided is an upper arm drive circuit that drives an upper arm switching element of a power conversion circuit, the upper arm drive circuit including: a first switching element having a drain electrode connected to a gate electrode of the upper arm switching element and a source electrode connected to one main electrode on a reference potential side of the upper arm switching element; a second switching element having a drain electrode connected to the gate electrode of the upper arm switching element; and a first diode and a second diode disposed between the drain electrode of the second switching element and the gate electrode of the upper arm switching element and between the drain electrode of the second switching element and the drain electrode of the first switching element, the first diode and the second diode being arranged in series with cathodes on a side of the second switching element and anodes on a side of the upper arm switching element, wherein a withstand voltage of the second diode is lower than a withstand voltage of the first diode, a recovery current of the second diode is lower than a recovery current of the first diode, and a withstand voltage of the first diode is in a range from 60 V to 100 V.

Further, a power conversion device of the present invention includes: the upper arm drive circuit described above, an upper arm switching element driven by the upper arm drive circuit, and a lower arm switching element connected in series to the upper arm switching element.

### Advantageous Effects of Invention

According to the present invention, since the recovery current of the first diode can be reduced by the second diode, it is possible to suppress malfunction of the upper arm switching element when a freewheeling current flows through a lower arm.

### BRIEF DESCRIPTION OF DRAWINGS

FIG. 1 is a circuit diagram of an upper arm drive circuit and a power conversion device according to an embodiment.

FIG. 2 is a waveform chart for explaining an operation according to the embodiment.

FIG. 3 is a waveform chart for explaining the operation according to the embodiment.

FIG. 4 is a circuit diagram of an upper arm drive circuit and a power conversion device according to a comparative example.

FIG. 5 is a waveform chart for explaining an ideal operation according to the comparative example.

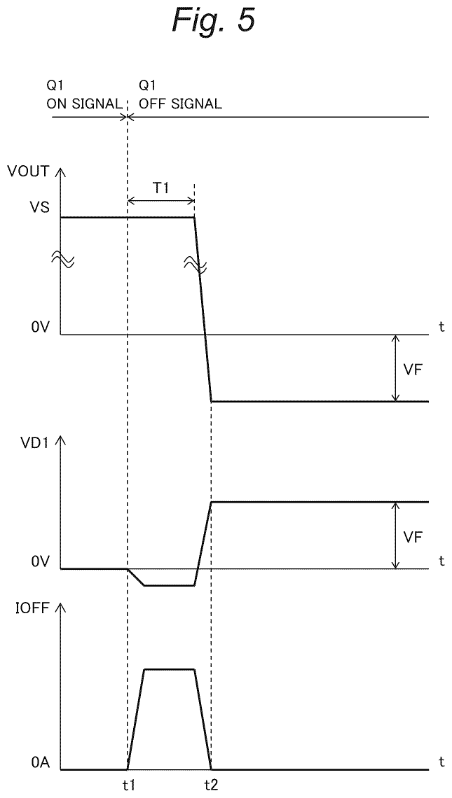

FIG. 6 is a waveform chart for explaining an actual operation according to the comparative example.

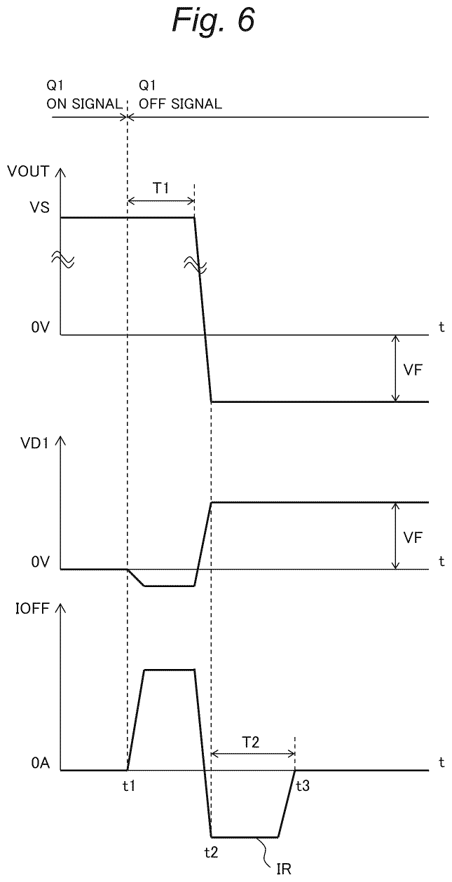

FIG. 7 is a circuit diagram of an upper arm drive circuit and a power conversion device according to a modification.

### DESCRIPTION OF EMBODIMENTS

Hereinafter, an embodiment of the present invention will be described with reference to the drawings. In the drawings and the embodiment, the same or similar components are denoted by the same reference numerals, and redundant description is omitted.

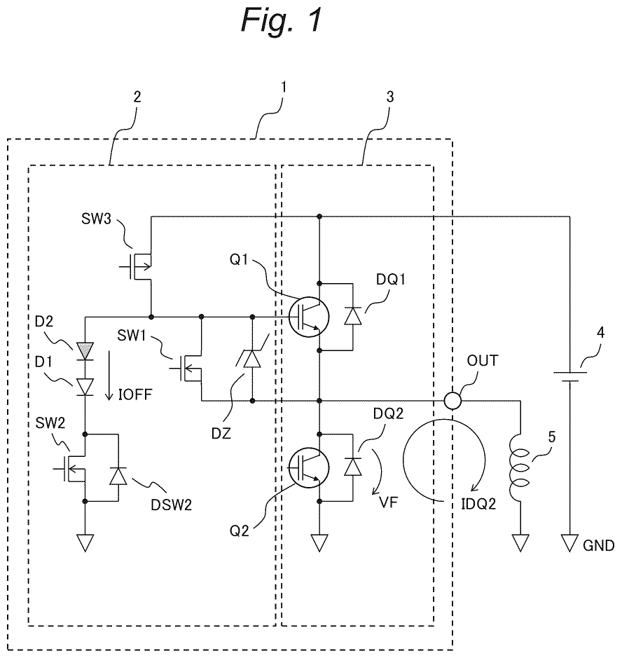

FIG. 1 is a circuit diagram of an upper arm drive circuit and a power conversion device according to an embodiment.

A power conversion device 1 of the embodiment includes an upper arm drive circuit 2, a lower arm drive circuit (not illustrated), and a power conversion circuit 3, and converts DC power from a DC power supply 4 into AC power to supply the AC power to a load 5 connected to an output terminal VOUT.

The power conversion circuit 3 includes an upper arm switching element Q1, a lower arm switching element Q2 connected in series to the upper arm switching element Q1, an upper arm freewheeling diode DQ1 connected in inverse-parallel to the upper arm switching element Q1, and a lower arm freewheeling diode DQ2 connected in inverse-parallel to the lower arm switching element Q2.

Each of the upper arm switching element Q1 and the lower arm switching element Q2 includes a gate electrode, one main electrode on a reference potential side, and the other main electrode. As the upper arm switching element Q1 and the lower arm switching element Q2, for example, an insulated gate bipolar transistor (IGBT), a metal oxide semiconductor field effect transistor (MOSFET), or the like can be used. In a case of the IGBT, the one main electrode is an emitter electrode, and the other main electrode is a collector electrode. In a case of the MOSFET, the one main electrode is a source electrode, and the other main electrode is a drain electrode. In the case of the MOSFET, a body diode built in the MOSFET can be used as the upper arm freewheeling diode DQ1 and the lower arm freewheeling diode DQ2.

The other main electrode of the upper arm switching element Q1 is connected to a high potential side of the DC power supply 4, the one main electrode of the lower arm switching element Q2 is connected to a ground potential GND (a low potential side of the DC power supply 4), and the output terminal OUT is connected to a connection node between the one main electrode of the upper arm switching element Q1 and the other main electrode of the lower arm switching element Q2.

In the present embodiment, a three-phase motor, for example, is assumed as the load 5, but only a configuration for one phase is illustrated in FIG. 1, and the rest is not illustrated.

The upper arm switching element Q1 is driven by the upper arm drive circuit 2, and the lower arm switching element Q2 is driven by the lower arm drive circuit (not illustrated).

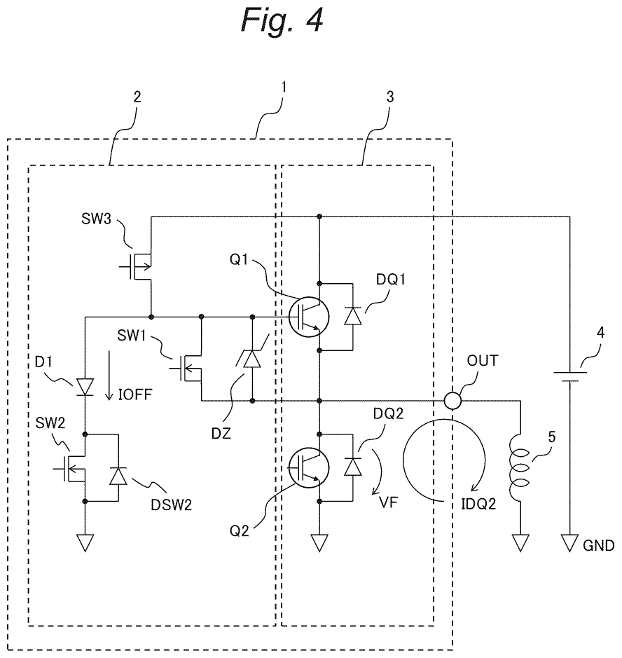

The upper arm drive circuit 2 of the embodiment includes a first switching element SW1, a second switching element SW2, a first diode D1, and a second diode D2. The upper arm drive circuit 2 also includes a third switching element SW3 and a Zener diode DZ. The upper arm drive circuit 2 illustrated in FIG. 1 is different from a comparative example illustrated in FIG. 4 in that the second diode D2 is additionally provided. Details of the second diode D2 will be described later.

In the first switching element SW1, the drain electrode is connected to the gate electrode of the upper arm switching element Q1, and the source electrode is connected to the one main electrode on the reference potential side of the upper arm switching element Q1.

The drain electrode of the second switching element SW2 is connected to the gate electrode of the upper arm switching element Q1. The source electrode of the second switching element SW2 is connected to the ground potential GND. The second switching element SW2 includes a body diode DSW2 of the second switching element.

The first switching element SW1 and the second switching element SW2 are controlled so as to extract a gate charge of the upper arm switching element Q1 in a case where the upper arm switching element Q1 is turned off.

The first diode D1 and the second diode D2 are arranged in series between the drain electrode of the second switching element SW2 and the gate electrode of the upper arm switching element Q1 and between the drain electrode of the second switching element SW2 and the drain electrode of the first switching element SW1, with cathodes on a side of the second switching element SW2 and anodes on a side of the upper arm switching element Q1. Here, although an example in which the first diode D1 is closer to the second switching element SW2 than the second diode D2 is illustrated in FIG. 1, the order of connection of the first diode D1 and the second diode D2 is not limited thereto, and the order of connection may be reversed. A withstand voltage of the second diode D2 in the embodiment is set to be lower than a withstand voltage of the first diode D1, and a recovery current of the second diode D2 is set to be lower than a recovery current of the first diode D1.

For example, the withstand voltage of the first diode D1 can be in the range from 30 V to 100 V, but the withstand voltage of the first diode D1 is more desirably in the range from 60 V to 100 V in consideration of an undershoot voltage of the output terminal voltage VOUT.

The withstand voltage of the second diode D2 is desirably in the range from 3 V to 20 V. The withstand voltage of the second diode D2 is more desirably higher than a forward voltage VF of the lower arm freewheeling diode, and thus is more desirably in the range from 10 V to 20 V.

Although it is assumed that a PN junction diode is used as the second diode D2, a Schottky barrier diode may be used in order to reduce the recovery current.

In the third switching element SW3, the drain electrode is connected to the other main electrode of the upper arm switching element Q1, and the source electrode is connected to the gate electrode of the upper arm switching element Q1.

In the Zener diode DZ, a cathode is connected to the gate electrode of the upper arm switching element Q1 and an anode is connected to the one main electrode on the reference potential side of the upper arm switching element Q1.

Although, in the present embodiment, NMOS is used as the first switching element SW1 and the second switching element SW2 and PMOS is used as the third switching element SW3, the present invention is not limited to this example as long as the same functions can be performed.

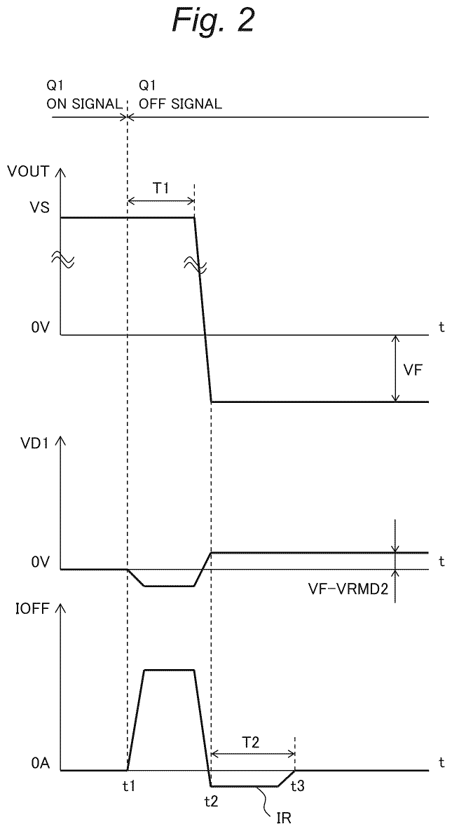

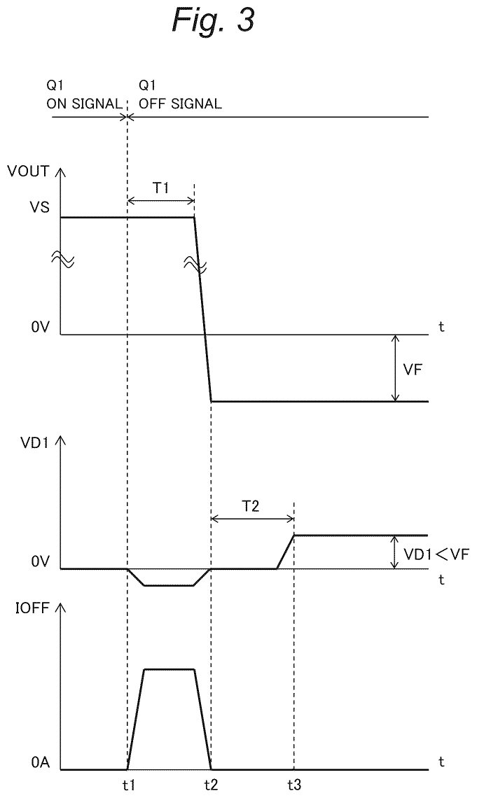

FIGS. 2 and 3 are waveform charts for explaining the operation according to the embodiment. In FIGS. 2 and 3, the vertical axis represents the output terminal voltage VOUT which is a voltage of the output terminal OUT, a voltage VD1 of the first diode (the withstand voltage direction is assumed to be positive), an upper arm OFF current IOFF, and the horizontal axis represents the time t.

Here, FIG. 2 is a waveform chart in a case where a relationship of the withstand voltage of the first diode D1>the forward voltage VF of the lower arm freewheeling diode>the withstand voltage of the second diode D2 is established. FIG. 3 is a waveform chart in a case where a relationship of the withstand voltage of the first diode D1>the withstand voltage of the second diode D2>the forward voltage VF of the lower arm freewheeling diode is established.

As illustrated in FIGS. 2 and 3, a drive signal applied to the gate electrode of the upper arm switching element Q1 is an ON signal until time t1. At this time, the lower arm switching element Q2 is turned off, the first switching element SW1 is turned off, the second switching element SW2 is turned off, and the third switching element SW3 is turned on. Specifically, when the third switching element SW3 is turned on, an ON signal is supplied to the gate electrode of the upper arm switching element Q1, the upper arm switching element Q1 is turned on, and the output terminal voltage VOUT becomes a DC power supply voltage VS. The DC power supply voltage VS is, for example, about 300 V, but is not limited thereto.

Thereafter, at the time t1, the first switching element SW1 is turned on, the second switching element SW2 is turned on, and the third switching element SW3 is turned off, and then the drive signal applied to the gate electrode of the upper arm switching element Q1 becomes an OFF signal, and the extraction of the gate charge of the upper arm switching element Q1 is started. Accordingly, from the time t1 to time t2, the forward voltage is applied to the first diode D1 and flows in the forward direction, and the upper arm OFF current IOFF flows.

After delay time T1 from the time t1, the upper arm switching element Q1 is turned off by the gate charge being extracted, a freewheeling current IDQ2 flows through the lower arm freewheeling diode DQ2 reversely connected to the lower arm switching element Q2, and the forward voltage VF of the lower arm freewheeling diode is generated in the output terminal voltage VOUT and becomes a negative voltage at the time t2. Since the forward voltage VF of the lower arm freewheeling diode includes a resistance component in addition to the forward voltage of the lower arm freewheeling diode DQ2, the magnitude of the forward voltage VF changes depending on the magnitude of the freewheeling current IDQ2, and is about 0.6 V to 10 V. As a result, at the time t2, a reverse bias voltage having the magnitude of the forward voltage VF of the lower arm freewheeling diode is applied to the first diode D1 and the second diode D2.

As illustrated in FIG. 2, in a case where the relationship of the withstand voltage of the first diode D1>the forward voltage VF of the lower arm freewheeling diode>the withstand voltage of the second diode D2 is established, the reverse current flows because avalanche occurs in the second diode D2, but the voltage of the reverse bias applied to the first diode D1 becomes VF-VRMD2 as decreasing by a withstand voltage VRMD2 of the second diode, and the recovery current IR decreases as compared with the case where the second diode D2 is not provided. Then, after time t3 after a recovery period T2 elapses, the recovery current IR does not flow.

In addition, as illustrated in FIG. 3, in a case where a relationship of the withstand voltage of the first diode D1>the withstand voltage of the second diode D2>the forward voltage VF of the lower arm freewheeling diode is established, since avalanche does not occur in the second diode D2, the voltage of the reverse bias applied to the first diode D1 becomes 0 V, the reverse current is blocked, and the recovery current IR does not flow. After the time t3 after the recovery period T2 elapses, the voltage of the reverse bias applied to the first diode D1 becomes higher than 0 V, but becomes lower than the forward voltage VF of the lower arm freewheeling diode, because the reverse bias is shared with the second diode D2. Then, the recovery current IR does not flow even after the time t3.

As described above, according to the present embodiment, since the recovery current IR of the first diode D1 can be reduced by the second diode D2, it is possible to suppress the malfunction of the upper arm switching element Q1 when the freewheeling current flows through the lower arm.

In addition, there is a trade-off that the withstand voltage of the diode decreases in order to reduce the recovery, but the recovery current IR can be reduced by additionally providing the second diode D2, so that the withstand voltage of the first diode D1 can be set higher than the forward voltage VF of the lower arm freewheeling diode.

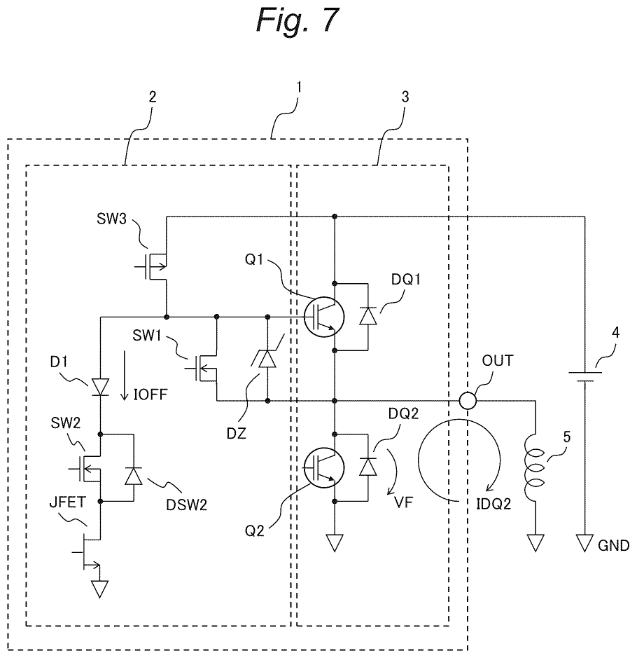

FIG. 7 is a circuit diagram of an upper arm drive circuit and a power conversion device according to a modification.

A power conversion device 1 of the modification is different from that of the embodiment in that the power conversion device 1 includes a junction field effect transistor JFET whose drain electrode is connected to a side of the source electrode of the second switching element SW2 instead of the second diode D2, and that the junction field effect transistor JFET is controlled so as to be turned on when an output terminal voltage VOUT (the same as a potential of the one main electrode on the reference potential side of the upper arm switching element Q1) is 0 V or higher, and to be turned off when the output terminal voltage VOUT is lower than 0 V.

A source electrode of the junction field effect transistor JFET is connected to the ground potential GND.

In this manner, by additionally providing the junction field effect transistor JFET and performing control according to a positive or negative value of the output terminal voltage VOUT, the recovery current IR can be reduced, and malfunction of the upper arm switching element Q1 when the freewheeling current flows through the lower arm can be suppressed.

Although the embodiment of the present invention has been described above, the present invention is not limited to the configurations described in the embodiment, and various modifications can be made within the scope of the technical idea of the present invention. In addition, a part or all of the configurations described according to the embodiment may be applied in combination.

### REFERENCE SIGNS LIST

1 power conversion device
2 upper arm drive circuit
3 power conversion circuit
4 DC power supply
5 load
Q1 upper arm switching element
Q2 lower arm switching element
DQ1 upper arm freewheeling diode
DQ2 lower arm freewheeling diode
OUT output terminal
SW1 first switching element
SW2 second switching element
SW3 third switching element
D1 first diode
D2 second diode
DZ Zener diode
DSW2 body diode of second switching element
GND ground potential
VS DC power supply voltage
VF forward voltage of lower arm freewheeling diode
VOUT output terminal voltage
VD1 voltage of first diode
IOFF upper arm OFF current
IDQ2 freewheeling current
IR recovery current
T1 delay time
T2 recovery period
VRMD2 withstand voltage of second diode
JFET junction field effect transistor

1. An upper arm drive circuit that drives an upper arm switching element of a power conversion circuit, the upper arm drive circuit comprising:
a first switching element having a drain electrode connected to a gate electrode of the upper arm switching element and a source electrode connected to one main electrode on a reference potential side of the upper arm switching element;
a second switching element having a drain electrode connected to the gate electrode of the upper arm switching element; and
a first diode and a second diode disposed between the drain electrode of the second switching element and the gate electrode of the upper arm switching element and between the drain electrode of the second switching element and the drain electrode of the first switching element, the first diode and the second diode being arranged in series with cathodes on a side of the second switching element and anodes on a side of the upper arm switching element, wherein
a withstand voltage of the second diode is lower than a withstand voltage of the first diode,
a recovery current of the second diode is lower than a recovery current of the first diode, and
a withstand voltage of the first diode is in a range from 60 V to 100 V.

2. The upper arm drive circuit according to claim 1, wherein the withstand voltage of the second diode is in a range from 3 V to 20 V.

3. The upper arm drive circuit according to claim 1, wherein the withstand voltage of the second diode is in a range from 10 V to 20 V.

4. The upper arm drive circuit according to claim 1, wherein the second diode is a PN junction diode.

5. The upper arm drive circuit according to claim 1, wherein the second diode is a Schottky barrier diode.

6. The upper arm drive circuit according to claim 1, wherein a source electrode of the second switching element is connected to a ground potential.

7. The upper arm drive circuit according to claim 1, wherein the first switching element and the second switching element are controlled so as to extract a gate charge of the upper arm switching element in a case where the upper arm switching element is turned off.

8. A power conversion device comprising:
the upper arm drive circuit according to claim 1;
an upper arm switching element driven by the upper arm drive circuit; and
a lower arm switching element connected in series to the upper arm switching element.

9. The power conversion device according to claim 8, further comprising
a lower arm freewheeling diode connected in inverse-parallel to the lower arm switching element, wherein
the withstand voltage of the first diode is higher than a voltage generated during freewheeling of the lower arm freewheeling diode.

10. The power conversion device according to claim 9, wherein the withstand voltage of the second diode is lower than the voltage generated during freewheeling of the lower arm freewheeling diode.

11. The power conversion device according to claim 9, wherein the withstand voltage of the second diode is higher than the voltage generated during freewheeling of the lower arm freewheeling diode.

12. An upper arm drive circuit that drives an upper arm switching element of a power conversion circuit, the upper arm drive circuit comprising:
a first switching element having a drain electrode connected to a gate electrode of the upper arm switching element and a source electrode connected to one main electrode on a reference potential side of the upper arm switching element;
a second switching element having a drain electrode connected to the gate electrode of the upper arm switching element;
a diode connected between the drain electrode of the second switching element and the gate electrode of the upper arm switching element and between the drain electrode of the second switching element and the drain electrode of the first switching element, the diode being disposed with a cathode on a side of the second switching element and an anode on a side of the upper arm switching element; and
a junction field effect transistor having a drain electrode connected to a side of a source electrode of the second switching element, wherein
the junction field effect transistor is controlled so as to be turned on in a case where the one main electrode of the upper arm switching element is 0 V or higher, and to be turned off in a case where the one main electrode is lower than 0 V.
